(19) United States
(12) Patent Application Publication
(10) Pub. No.: US 2006/0249819 A1
(43) Pub. Date: Nov. 9, 2006

(54) Lead frame having contacting pins of different thickness

(75) Inventor: Hsin-Chen Yang, Taichung County (TW)

Correspondence Address: BACON & THOMAS, PLLC, 625 SLATERS LANE, FOURTH FLOOR, ALEXANDRIA, VA, 22314, US

(73) Assignee: LINGSEN PRECISION INDUSTRIES, LTD., TAICHUNG (TW)

(21) Appl. No.: 11/144,639

(22) Filed: Jun. 6, 2005

(30) Foreign Application Priority Data
Apr. 26, 2005 (TW) 94206543

(51) Int. Cl. H01L 23/495

(52) U.S. Cl. 257/666

(57) ABSTRACT

A lead frame has contacting pins of different thickness arranged around a die pad and spaced from one another and the die pad to fit the demands of the designed integrated circuit, for enabling the fabricated integrated circuit to have the desired optimum electric characteristics.

### BACKGROUND OF THE INVENTION

1. Field of the Invention

The present invention relates to a metal lead frame for IC (integrated circuit) packaging and more particularly, to a meal lead frame, which has contacting pins of different thickness.

2. Description of the Related Art

Following fast development of high technology, it is the technology necessary for the realization of light, thin, short and small products. Therefore, IC performance has been continuously improved. In consequence, the demands on electric characteristics for a communication IC such as RF (Radio Frequency) IC are critical.

For designing an IC using a metal lead frame as a carrier, the designer must consider the performance of the whole IC when designing the lead frame. In order to meet the demands, the designed lead frame may have to match with other electronic components so as to achieve the desired optimum performance. For example, adding a passive component (inductor, capacitor, or resistor) to change the impedance and the inductance so as to obtain the desired electric characteristics. However, when packaging of a RF IC, the use of passive components with the designed metal lead frame may still not be able to obtain the desired optimum electric characteristics.

Therefore, it is desirable to provide a lead frame for IC packaging that eliminates the aforesaid problem.

### SUMMARY OF THE INVENTION

The present invention has been accomplished under the circumstances in view. It is the main object of the present invention to provide a metal lead frame for IC packaging, which has the contacting pins made in different thickness so that the packaged IC can have the desired optimum electric characteristics.

According to the present invention, the lead frame comprises at least one die pad, and a plurality of contacting pins arranged around the at least one die pad. The contacting pins have different thickness, and are spaced from one another and the at least one die pad by space. The contacting pins can be coated with a layer of copper by plating to increase the thickness, or etched or mechanically ground to reduce the thickness.

### BRIEF DESCRIPTION OF THE DRAWINGS

FIG. 1 is a top view of a lead frame for IC packaging according to the present invention.

FIG. 2 is a schematic view of a part of the lead frame according to the present invention, showing contacting pins of different thickness.

FIGS. 3A-3D are schematic drawings show a copper plating proceeding of the contacting pins of the lead frame according to the present invention.

FIG. 4 is a top view of an array of lead frames for IC packaging according to the present invention.

### DETAILED DESCRIPTION OF THE INVENTION

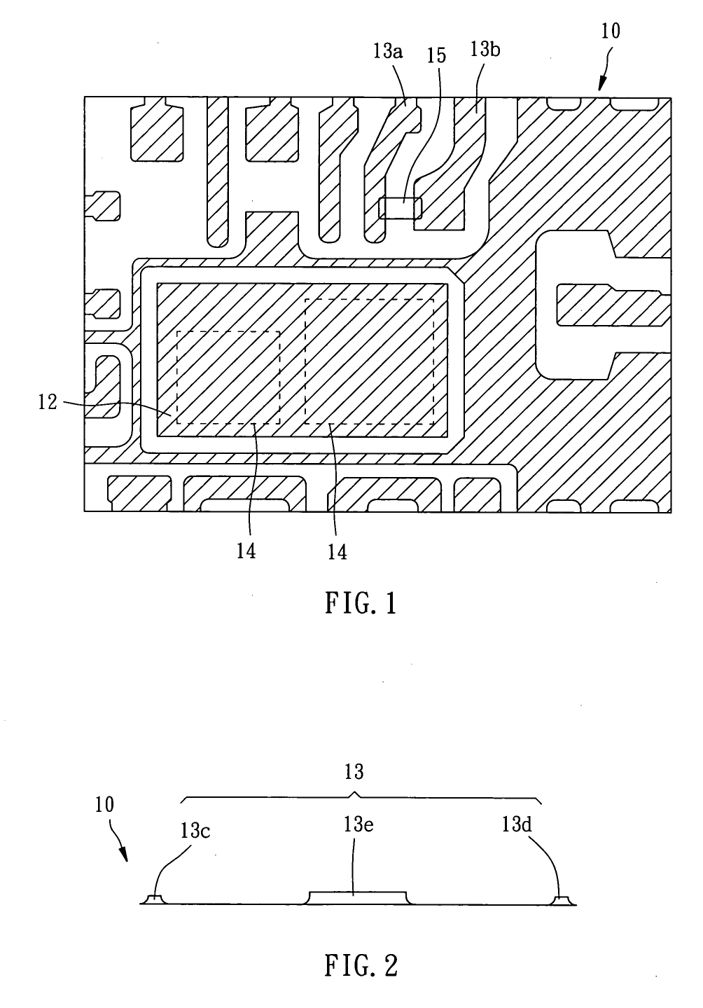

Referring to FIGS. 1-3, a lead frame 10 in accordance with the present invention is shown comprising a die pad 12 and a plurality of contacting pins 13.

The die pad 12 holds a chip or chips 14. The contacting pins 13 are arranged around the die pad 12. The contacting pins 13 are respectively spaced from the die pad 13 and spaced from one another by space. Further, a passive component 15 is connected between two contacting pins 13a and 13b, as shown in FIG. 1.

In the aforesaid lead frame 10, the contacting pins 13 have different thickness subject to the designed integrated circuit. For example, contacting pins 13c and 13d shown in FIG. 2 have same thickness, and the thickness of contacting pin 13e is greater than contacting pins 13c and 13d.

The increasing or reducing of the thickness of the contacting pins 13 can be achieved by many methods including the following three methods:

1. Using copper plating techniques to coat the contacting pins 13 with a layer of copper so as to increase the thickness of the contacting pins 13.

2. Using etching techniques to reduce the thickness of the contacting pins 13, i.e., employing photolithographic technology to etch the contacting pins 13 of the lead frame 10, reducing thickness of the contacting pins 13 to the desired level.

3. Using mechanical grinding techniques to grind the contacting pins 13 of the lead frame 10, thereby reducing the thickness of the contacting pins 13 to the desired level.

The aforesaid first method of coating the contacting pins 13 with a layer of copper comprises the steps of:

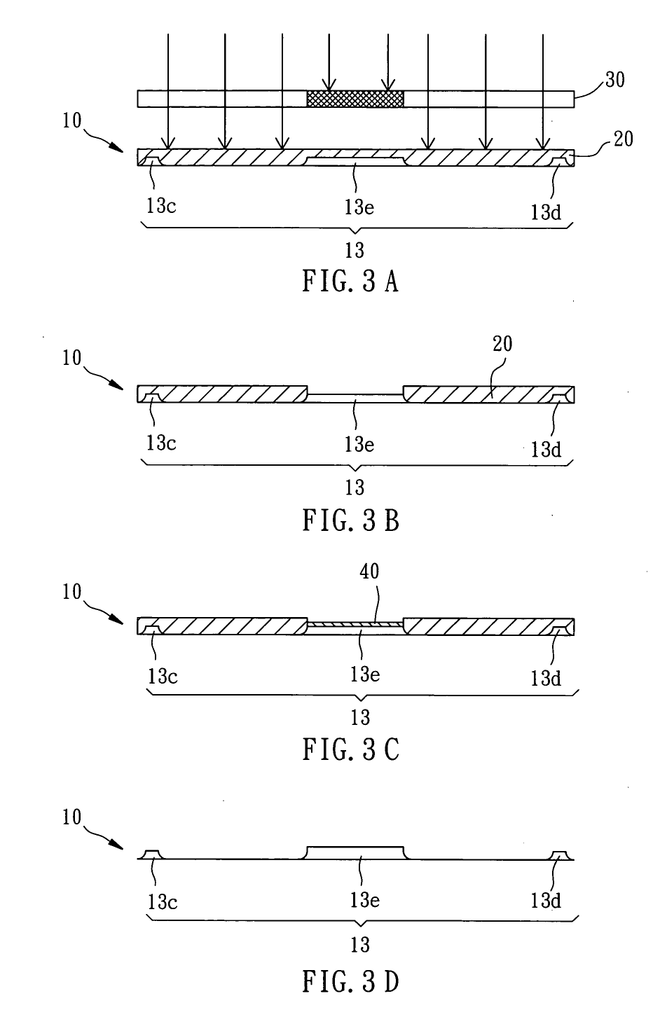

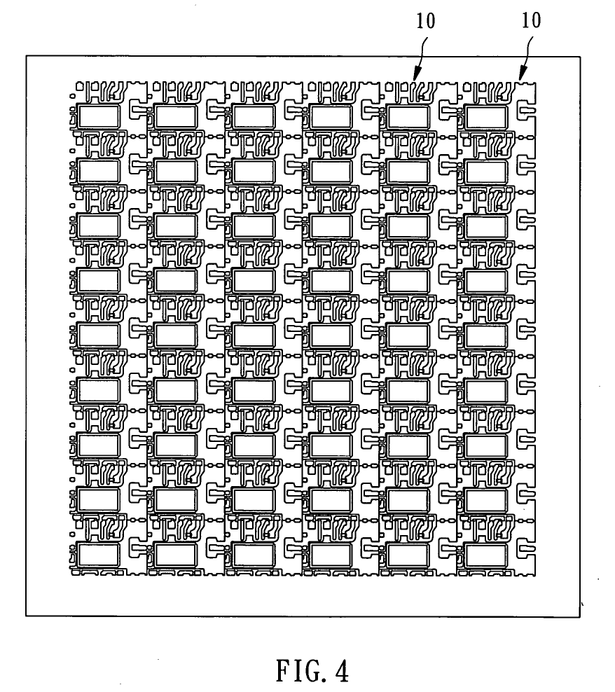

a) covering the lead frame 10 with a layer of negative photoresist 20, and then using a photomask 30 to mask the assigned part of the lead frame 10, for example, contacting pin 13e, and then employing a light to the lead frame 10 through the photomask 30b (see FIG. 3A);

b) removing the masked negative photoresist 20 from the lead frame 10 by washing so that the assigned contacting pin 13e is exposed to the outside (see FIG. 3B);

c) plating the assigned contacting pin 13e with a layer of copper 40 to increase the thickness of the assigned contacting pin 13e to the desired level (see FIG. 3C); and

d) stripping off the layer of negative photoresist 20 from the lead frame 10 with a chemical solution.

The use of a passive component 15 in IC packaging can adjust the impedance of the related contacting pins 13 so that the IC can have optimum electric characteristics. However, for an IC package of high radio frequency, the demands on electric characteristics are critical. If the use of passive components cannot achieve the desired optimum electric characteristics, changing the thickness of the contacting pins of the lead frame can obtain the desired impedance and inductance, enabling the IC package to have the desired optimum electric characteristics.

Further, multiple packaging units may be arranged together during fabrication. For example, multiple lead frames 10 are arranged in an array on a plane for fabrication, thereby saving much the manufacturing cost and efficiency.

The lead frame having contacting pins of different thickness for IC packaging functions smoothly to provide all of the features discussed earlier.

Although a particular embodiment of the invention has been described in detail for purposes of illustration, various modifications and enhancements may be made without departing from the spirit and scope of the invention. Accordingly, the invention is not to be limited except as by the appended claims.

What is claimed is:

1. A lead frame comprising:
at least one die pad; and
a plurality of contacting pins arranged around said at least one die pad, said contacting pins being spaced from one another and said at least one die pad by space;
wherein said contacting pins have different thickness.

2. The lead frame as claimed in claim 1, wherein said contacting pins include a comparatively thicker contacting pin that is coated with a layer of copper.

3. The lead frame as claimed in claim 1, wherein said contacting pins include a comparatively thinner contacting pin that is etched to the desired thickness.

4. The lead frame as claimed in claim 1, wherein said contacting pins include a comparatively thinner contacting pin that is mechanically ground to the desired thickness.
